(19) United States
(12) Patent Application Publication
(10) Pub. No.: US 2011/0043102 A1
(43) Pub. Date: Feb. 24, 2011

(54) ORGANIC LUMINESCENT DEVICE AND A PRODUCTION METHOD FOR THE SAME

(75) Inventors: Jung-Hyoung Lee, Daejeon Metropolitan City (KR); Yun-Hye Hahm, Daejeon Metropolitan City (KR); Jeoung-Kwen Noh, Daejeon Metropolitan City (KR); Jung-Bum Kim, Daejeon Metropolitan City (KR)

Correspondence Address: MCKENNA LONG & ALDRIDGE LLP, 1900 K STREET, NW, WASHINGTON, DC, 20006, US

(73) Assignee: LG CHEM, LTD., Seoul (KR)

(21) Appl. No.: 12/864,209

(22) PCT Filed: Jan. 23, 2009
(86) PCT No.: PCT/KR2009/000377

§ 371 Date: Nov. 11, 2010

(30) Foreign Application Priority Data
Jan. 23, 2008 (KR) 10-2008-0007004

(51) Int. Cl. H05B 33/14; H01J 9/00

(52) U.S. Cl. 313/504; 445/58

(57) ABSTRACT

The present invention provides an organic light emitting device that comprises a substrate, a first electrode, two or more organic material layers, and a second electrode sequentially layered, wherein the organic material layers include a light emitting layer, and among the organic material layers, the organic material layer that is contacted with the second electrode includes metal oxide, and a method for manufacturing the same.

### TECHNICAL FIELD

The present invention relates to an organic light emitting device and a method for manufacturing the same. More particularly, the present invention relates to an organic light emitting device that comprises a layer for preventing a damage to an organic material layer while an electrode is formed on the organic material layer in the course of manufacturing the organic light emitting device and a method for manufacturing the same.

This application claims priority from Korean Patent Application No. 10-2008-0007004 filed on Jan. 23, 2008 in the Korean Intellectual Property Office, the disclosure of which is incorporated herein by reference in its entirety.

### BACKGROUND ART

An organic light emitting device (OLED) comprises two electrodes (anode and cathode) and one or more organic material layers that are disposed between the electrodes. In the organic light emitting device having the above structure, if voltage is applied between two electrodes, a hole and an electrode are transferred from an anode and a cathode, respectively, to an organic material layer, they are recombined to form an exciton, and a photon corresponding to a difference in energy is emitted while the exciton falls down to a base state. Based on this principle, the organic light emitting device emits visible rays, and an information display device or a lighting device may be manufactured by using this.

In the organic light emitting device, in a bottom emission type, light that is generated in the organic material layer is emitted toward a substrate, and in a top emission type, light is emitted in a direction that is opposite to the substrate. In a both-side emission type, light is emitted in both a substrate direction and a substrate opposite direction.

In a passive matrix organic light emitting device (passive matrix OLED; PMOLED) display, a cathode and an anode are perpendicular to each other, and an area of a place at which the cathode and the anode cross each other is used as a pixel. Therefore, the bottom emission type and the top emission type are not largely different from each other in views of an effective display aperture ratio.

However, the active matrix organic light emitting device (active matrix OLED; AMOLED) display uses a thin-film transistor (TFT) as a switching device for driving each pixel. In the manufacturing of the TFT, since a high temperature process (at least several hundreds ° C. or more) is required in general, the TFT arrangement that is required to drive the organic light emitting device is performed on the glass substrate before the electrode and the organic material layer are deposited. Here, as described above, the glass substrate on which the TFT arrangement exists is called a backplane. In the case of when the active matrix organic light emitting device display using the backplane is manufactured by using the bottom emission type, since a portion of light that is emitted to the substrate is blocked by the arrangement of TFT, an effective area ratio of display is reduced. This problem becomes more serious in the case of when a plurality of TFTs are provided to one pixel in order to manufacture a sophisticated display. Therefore, in the case of the active matrix organic light emitting device, it is required to manufacture it in a top emission type.

In the top emission or both-side emission organic light emitting device, an electrode that is not contacted with the substrate and is opposite to the substrate should be transparent in a visible ray area. In the organic light emitting device, a conductive oxide film such as IZO (indium zinc-oxide) or ITO (indiumtin-oxide) is used as a transparent electrode. However, since the conductive oxide film has the very high work function (generally, >4.5 eV), in the case of when a cathode is formed by using it, since it is difficult to inject electrons from the cathode to the organic material layer, operation voltage of the organic light emitting device is largely increased, and important device properties such as light emission efficiency and the like are reduced. Therefore, it is required that the top emission or both-side emission organic light emitting device having a structure in which a substrate, a cathode, an organic material layer and an anode are sequentially layered, that is, an inverted structure, is manufactured.

In addition, in the active matrix organic light emitting device, in the case of when an a-Si TFT (a-Si thin-film transistor) is used as a TFT, since the a-Si TFT has physical properties where a main electric charge carrier is an electrode, the a-Si TFT has a structure where a source junction and a drain junction are doped in an n-type. Therefore, in the case of when the active matrix device using the a-Si TFT is manufactured, the cathode of the organic light emitting device is first formed on the source junction or the drain junction formed on the substrate, the organic material layer is formed, and the conductive oxide film anode such as ITO or IZO are sequentially formed. In other words, the organic light emitting device having the inverted structure is manufactured, which is preferable in views of electric charge injection and process simplification.

However, in the process for manufacturing the organic light emitting device having the inverted structure, in the case of when the electrode disposed on the organic material layer is formed by using the conductive oxide film such as IZO or ITO having the transparency, if a resistive heating evaporation method is used, in the evaporation process by heat, since the intrinsic chemical composition ratio of oxides is changed because of thermal decomposition and the like, properties such as electric conductivity and visible ray transmission are lost. Therefore, when the conductive oxide film is deposited, the resistive heating evaporation method is not used, and in most case, a method using a plasma such as sputtering is used.

However, in the case of when the electrode is formed on the organic material layer by using the method such as sputtering, because of the electric charge particles that exists in the plasma used in the sputtering process, the organic material layer may be damaged. Moreover, in the sputtering process, kinetic energy of atoms forming the electrode on the organic material layer is in the range of several tens to several thousands eV, which is very high as compared to the case of kinetic energy of atoms in the deposition by heating of the resistor (generally, <1 eV). Therefore, physical properties of the organic material layer may be reduced due to bombardment of particles to the organic material layer to reduce injection and transportation properties of electrons or holes and light emitting properties. In particular, the organic material mainly including a covalent bond of C and H and a thin film including the organic material are very weak to a plasma during a sputtering process as compared to an inorganic semiconductor (for example, Si, Ge, GaAs and the like), and it is impossible to recover the damaged organic material.

Therefore, it is required to remove or minimize a damage to organic material layer, which may occur when an electrode is formed on an organic material layer by using a method such as sputtering in order to manufacture the excellent organic light emitting device.

There is a method of controlling a forming rate of thin film during sputtering in order to avoid a damage to organic material layer, which may occur when an electrode is formed on an organic material layer by using sputtering. For example, RF power or DC voltage may be reduced in an RF or DC sputtering process to reduce the number of atoms and average kinetic energy of atoms transferred from a sputtering target to an organic light emitting device substrate, thus reducing a sputtering damage to organic material layer.

Examples of another method for preventing a damage to the organic material layer due to the sputtering include a method of increasing a distance between a sputtering target and an organic light emitting device substrate to increase a chance of collision of atoms transferred from a sputtering target to a substrate and sputtering gases (for example, Ar), thus intentionally reducing kinetic energy of the atoms.

However, in the above methods, since a deposition rate is very low, a process time is very long during a sputtering step, accordingly, a batch processing amount required to manufacture the organic light emitting device is significantly reduced. Moreover, since particles having high kinetic energy may reach the surface of the organic material layer during the sputtering process having the low deposition rate, it is difficult to effectively remove a damage to the organic material layer due to the sputtering.

A document [“Transparent organic light emitting devices” Applied Physics Letters Volume 68, May 1996, p. 2606] discloses a method of forming a cathode, which comprises forming an anode and an organic material layer on a substrate, forming a thin Mg:Ag mixed metal film having an excellent electron injection performance, and depositing an ITO thereon using sputtering. The structure of the organic light emitting device of the above document is illustrated in FIG. 1. However, the Mg:Ag metal film is disadvantageous in that transmission of visible rays is low as compared to that of ITO or IZO and there is a relatively complicated process management.

A document [“A metal-free cathode for organic semiconductor devices” Applied Physics Letters Volume 72, April 1998, p. 2138] discloses that in an organic light emitting device having a structure including a substrate, an anode, an organic material layer and a cathode sequentially layered, a CuPc layer that is relatively strong in respects to sputtering is deposited between the organic material layer and the cathode in order to prevent a sputtering damage to organic material layer due to deposition of a cathode. FIG. 2 illustrates the structure of the organic light emitting device disclosed in the above document.

However, in general, CuPc is used as a hole injecting layer, and in the above document, CuPc acts as an electron injecting layer with a sputtering damage between the organic material layer and the cathode of the organic light emitting device including a substrate, an anode, an organic material layer and a cathode sequentially layered. Therefore, electric charge injection properties of the organic light emitting device and relating device properties regarding such as current efficiency and the like are reduced. Moreover, since absorption of light by CuPc is significant in a visible ray area, performance of the device is rapidly reduced as the thickness of the film is increased.

A document [“Interface engineering in preparation of organic surface emitting diodes” Applied Physics Letters, Volume 74, May 1999, p. 3209] discloses that another electron injecting layer, for example, a Li thin film, is deposited between an electron transporting layer and a CuPc layer in order to improve a low electron injection property of a CuPc layer. FIG. 3 illustrates the structure of the organic light emitting device disclosed in the above document. However, the method of preventing a sputtering damage is problematic in that an additional metal thin film is required and it is difficult to control a process.

Therefore, in the organic light emitting device having the inverted structure, there is a need to develop a technology for preventing a damage to organic material layer when an anode is formed.

Meanwhile, in a typical organic light emitting device, a thin LiF layer that helps electron injection is deposited between an electron transporting layer and a cathode layer to improve an electron injection property from the cathode to the electron transporting layer (ETL). However, in the case of when the above method is used, it is known that if the cathode electrode is used as a top contact electrode, the electron injection property is excellent, but if the cathode electrode having the inverted structure is used as a bottom contact electrode, the electron injection property is significantly reduced.

A document [“An effective cathode structure for inverted top-emitting organic light-emitting device” Applied Physics Letters, Volume 85, September 2004, p 2469] discloses an effort for improving an electron injection property using a structure including a very thin Alq3-LiF—Al layer between a cathode electrode and an electron transporting layer, but is disadvantageous in that a process is very complicated. Additionally, a document [“Efficient bottom cathodes for organic light-emitting device” Applied Physics Letters, Volume 85, August 2004, p 837] discloses an effort of depositing a thin Al layer between a metal-hallide layer (NaF, CsF, and KF) and an electron transporting layer to improve an electron injection property. However, this process is problematic in that a novel layer should be used.

Therefore, in the case of the organic light emitting device having the inverted structure, a method of improving an electron injection property while a manufacturing process of a device is simple is required.

### DISCLOSURE

### Technical Problem

The present inventors have found that in an organic light emitting device that has a structure in which a substrate, a first electrode, an organic material layer including two or more layers and second electrode are sequentially layered, among the organic material layers, by doping metal oxides into the organic material layer that is contacted with the second electrode, a damage of the organic material layer that may occur when the second electrode is formed may be minimized. Thereby, without a negative affect to characteristics of the device, a top emission or a both-side emission organic light emitting device that has an inverse structure in which a substrate, a cathode, an organic material layer and an anode are sequentially layered may be manufactured.

Therefore, it is an object of the present invention to provide an organic light emitting device that comprises an organic material layer that is capable of preventing a damage of the organic material layer when an electrode of the organic light emitting device is formed and a method for manufacturing the same.

### Technical Solution

An embodiment of the present invention provides an organic light emitting device that includes a substrate, a first electrode, two or more organic material layers, and a second electrode sequentially layered, wherein the organic material layers include a light emitting layer, and among the organic material layers, the organic material layer that is contacted with the second electrode includes metal oxide.

Another embodiment of the present invention provides the organic light emitting device that is characterized in that the organic light emitting device is a top light emitting device or a both-side light emitting device.

Another embodiment of the present invention provides the organic light emitting device that is characterized in that the second electrode is formed by a thin film forming technology that is capable of providing a damage to the organic material layer without the presence of the organic material layer including the metal oxide by accompanying particles having electric charges or high kinetic energy.

Another embodiment of the present invention provides the organic light emitting device that is characterized in that the second electrode includes metal having a work function in the range of 2 to 6 eV or a conductive oxide film.

Another embodiment of the present invention provides the organic light emitting device that is characterized in that the first electrode is a cathode, and the second electrode is an anode.

Another embodiment of the present invention provides a method for manufacturing an organic light emitting device, which includes the steps of sequentially layering a first electrode, two or more organic material layers and a second electrode on a substrate, wherein one layer of the organic material layers is formed as a light emitting layer and the organic material layer that is contacted with the second electrode among the organic material layers is formed by doping metal oxide into an organic material.

### Advantageous Effects

In the present invention, because of an organic material that includes the metal oxide, a damage of an organic material layer, which may occur when an electrode is formed on the organic material layer, may be prevented. Thus, without a damage of the organic material layer, which may occur when an electrode is formed on the organic material layer, an organic light emitting device that has a structure in which a substrate, a cathode, an organic material layer and an anode are sequentially layered may be manufactured. In addition, in the organic light emitting device that has the above inverse structure, in the case of when characteristics of a hole transporting layer (HTL) material and metal oxide are mixed with each other, an organic light emitting device having a largely reduced leakage current may be manufactured without an increase in operation voltage. The leakage current is considered a problem of a hole transporting layer (HTL).

### DESCRIPTION OF DRAWINGS

FIG. 1 illustrates a structure of a known organic light emitting device in which a Mg:Ag layer is applied between an organic material layer and an ITO cathode in an organic light emitting device in which a substrate, an anode, an organic material layer and a cathode (ITO) are sequentially layered;

FIG. 2 illustrates a structure of a known organic light emitting device in which a CuPc layer is applied between an organic material layer and an ITO cathode in an organic light emitting device in which a substrate, an anode, an organic material layer and a cathode (ITO) are sequentially layered;

FIG. 3 illustrates a structure of a known organic light emitting device in which an Li thin film (electron injecting layer) is layered as an organic material layer that is contacted with the CuPc layer in the organic light emitting device that is shown in FIG. 2;

FIG. 4 illustrates a structure of a top emission organic light emitting device according to the present invention;

FIG. 5 illustrates a structure of a both-side emission organic light emitting device according to the present invention;

FIG. 6 is a graph that illustrates leakage current characteristics of organic light emitting devices manufactured in Example and Comparative Example according to the present invention; and

FIG. 7 is a graph that illustrates luminance characteristics of organic light emitting devices manufactured in Example and Comparative Example according to the present invention.

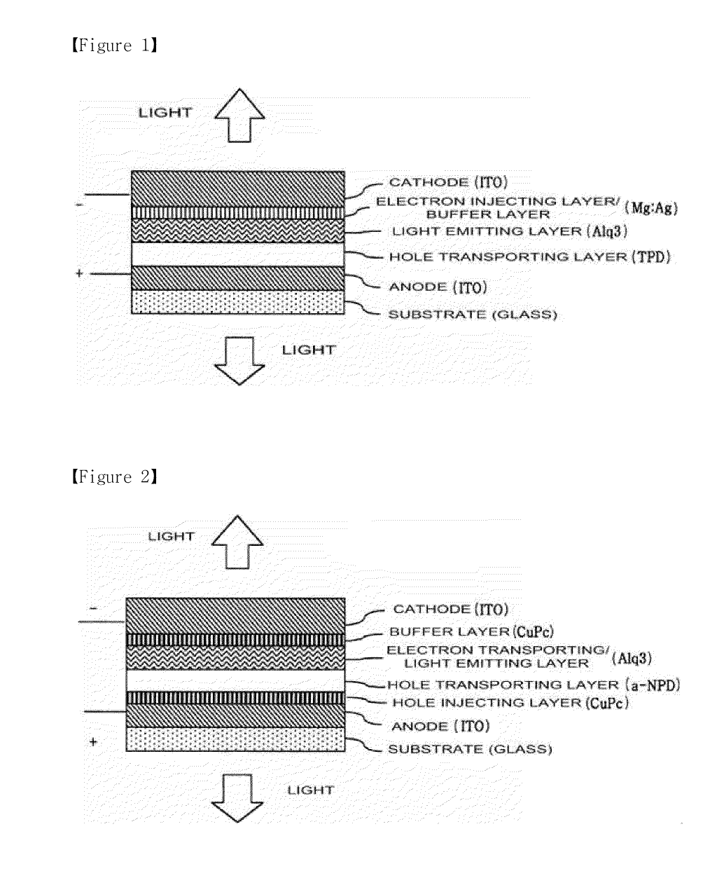

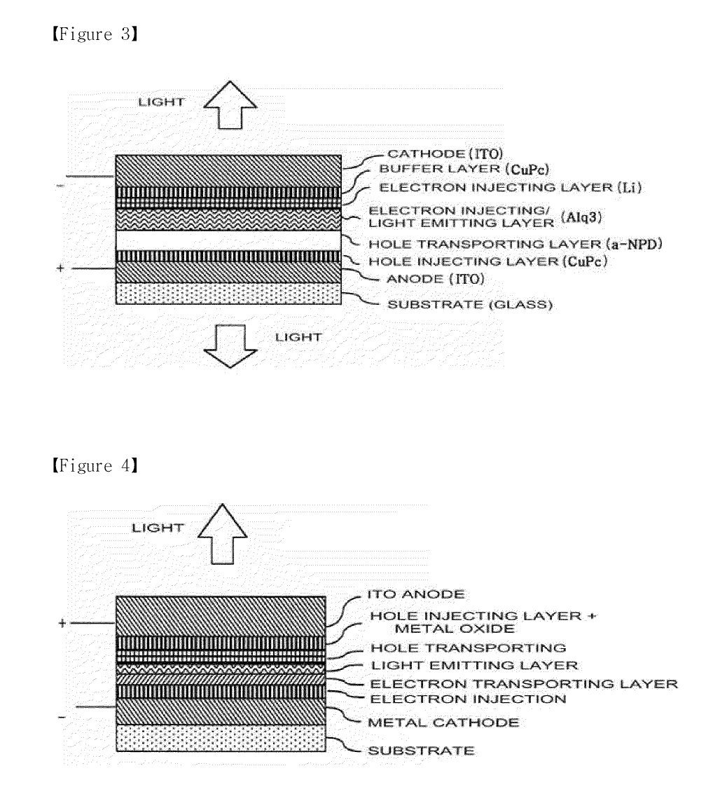

### BEST MODE

Hereinafter, the present invention will be described in detail.

An organic light emitting device according to the present invention comprises a substrate, a first electrode, two or more organic material layers, and a second electrode sequentially layered, wherein the organic material layers include a light emitting layer, and among the organic material layers, the organic material layer that is contacted with the second electrode includes metal oxide.

Examples of the metal oxide may include one or more that are selected from the group consisting of MoO₃, WO₃ and V₂O₅, and it is preferable that it is doped into the organic material layer that is contacted with the second electrode before the second electrode is deposited.

The metal oxide is included preferably in a concentration of 1 wt % or more and less than 100 wt % in respects to a composition for forming the organic material layer that is contacted with the second electrode, more preferably included in a concentration in the range of 5 to 50 wt %, and most preferably in a concentration in the range of 10 to 30 wt %. In the case of when the concentration of the metal oxide is less than 1 wt %, a damage of an organic film may occur when the second electrode is formed. In addition, in the case of when the concentration of the metal oxide is 100 wt %, since the hole injection is reduced, the light emitting efficiency may be reduced.

In the organic light emitting device according to the present invention, the organic material layer that includes the metal oxide is contacted with the second electrode, and a damage of the organic material layer may be prevented when the second electrode is formed on the organic material layer in the course of manufacturing the organic light emitting device. For example, in the case of when a method such as sputtering is used when the second electrode, in particular, the transparent second electrode is formed on the organic material layer, the organic material layer may be electrically or physically damaged by particles that are charged and generated by a plasma or atoms having high kinetic energy while a sputtering process is carried out. The damage of the organic material layer may occur when the electrode is formed on the organic material layer by sputtering or another thin film forming technology that is capable of providing damage to the organic material layer by accompanying electric charges or the particles having high kinetic energy. However, in the case of when the second electrode is formed on the organic material layer that includes metal oxide by using the above method, an electric or physical damage of the organic material layer may be minimized or prevented.

In addition, in the case of when the metal oxide layer is included between the second electrode and the organic material layer that is contacted with the second electrode, while the operation voltage is rapidly increased as the thickness of the metal oxide layer is increased, by doping the metal oxide to the organic material layer that is contacted with the second electrode, an increase in voltage may be reduced. In addition, in the case of when the property of the hole injecting layer (HIL) material that is represented by the following Formula 1 and the property of the metal oxide are mixed with each other, a leakage current that is a problem of the hole injecting layer (HIL) may be largely reduced.

In the present invention, as described above, when the second electrode is formed on the organic material layer, by minimizing or preventing the electric or physical damage of the organic material layer, a reduction in property of light emitting by the damage of the organic material layer may be prevented. In addition, since the damage of the organic material layer in the second electrode forming process may be prevented, when the second electrode is formed, control of process variance and optimization of the process device may be easily carried out, and the process treatment amount may be improved. In addition, the selection of the material and deposition method of the second electrode may be various. For example, in addition to the transparent electrode, the metal thin film such as Al, Ag, Mo, Ni and the like may use a thin film forming technology for damaging the organic material layer without the organic material layer including the metal oxide by accompanying electric charges or particles having high kinetic energy as sputtering, a physical vapor deposition (PVD) method using a laser, an ion beam assisted deposition method or a similar method.

In the organic light emitting device according to the present invention, by a function of the organic material layer that includes the metal oxide, the material and deposition method of the second electrode may be variously selected, thus, when an active matrix organic light emitting device using a top or both-side emission light emitting device or a-Si TFT is manufactured, an organic light emitting device that has a structure in which a substrate, a cathode, an organic material layer and an anode are sequentially layered without a problem of a damage of an organic material layer may be manufactured.

In addition, in the present invention, by using the organic material layer that includes the metal oxide, an electric property of the organic light emitting device may be improved. For example, in the organic light emitting device according to the present invention, in a reverse bias state, since a leakage current is reduced, a current-voltage property is largely improved, thus a very apparent rectification property is shown. Here, the rectification property is a general property of a diode and means a property in which the intensity of current in an area to which a reverse direction voltage is applied is very small as compared to the intensity of current in an area to which a forward direction voltage is applied.

In the present invention, the optimum thickness of the organic material layer that includes the metal oxide may be changed according to a factor of a sputtering process, which is used when the second electrode is formed, for example, a deposition rate, RF power, and DC voltage. For example, in general, in order to carry out the rapid deposition, in the sputtering process using high voltage and power, the optimum thickness of the organic material layer is increased. In the present invention, it is preferable that the thickness of the organic material layer that includes the metal oxide is 20 nm or more, and it is more preferable that the thickness is 50 nm or more. In the case of when the thickness of the organic material layer is less than 20 nm, the layer may act as a hole injecting or transporting layer, but since the surface roughness is increased, a reduction in hole injection may occur. Meanwhile, it is preferable that the thickness of the organic material layer is 100 nm or less. In the case of when the thickness of the layer is more than 100 nm, the manufacturing process time of the device is very long, and the color coordinate change may occur because of an increase in operation voltage of the device and a cavity effect.

In the present invention, the organic material layer that includes the metal oxide may be manufactured by forming it between the anode and the cathode by using a vacuum deposition method or a solution coating method. Examples of the solution coating method include spin coating, dip coating, doctor blading, inkjet printing or heat transferring method, but are not limited thereto. If necessary, the organic material layer that includes the metal oxide may further include another material.

Meanwhile, in the organic light emitting device according to the present invention, it is preferable that one or more organic material layers include a compound that that is represented by the following Formula 1, and it is more preferable that the organic material layer that is contacted with the second electrode among the organic material layers is used as the hole injecting layer.

Detailed examples of the hole injection material for forming the hole injecting layer include one or more that are selected from the group consisting of organic materials of metal porphyrin, oligothiophene, organic materials of arylamine series, organic materials of hexanitrile hexaazatriphenylene series, organic materials of quinacridone series, organic materials of perylene series, and conductive polymers of anthraquinone, polyaniline, and polythiophene series, but are not limited thereto. Preferably, the compound that is represented by the following Formula 1 may be used. By using it while the metal oxide is doped into the hole injection material, excellent properties, in detail, reduction in energy level and leakage current and an increase in voltage may be prevented.

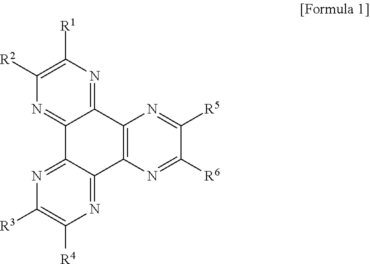

wherein R¹ to R⁶ are each selected from the group consisting of hydrogen, halogen atom, nitrile (—CN), nitro (—NO₂), sulfonyl (—SO₂R), sulfoxide (—SOR), sulfoneamide (—SO₂NR), sulfonate (—SO₃R), trifluoromethyl (—CF₃), ester (—COOR), amide (—CONHR or —CONRR′), substituted or unsubstituted straight- or branched-chained C₁-C₁₂ alkoxy, substituted or unsubstituted straight- or branched-chained C₁-C₁₂ alkyl, substituted or unsubstituted aromatic or nonaromatic heterocycle, substituted or unsubstituted aryl, substituted or unsubstituted mono- or di-arylamine, and substituted or unsubstituted aralkylamine, and R and R′ are each substituted or unsubstituted C₁-C₆₀ alkyl, substituted or unsubstituted aryl and substituted or unsubstituted 5-7 membered heterocycle.

Detailed examples of the compound of Formula 1 include compounds of the following Formulas 1-1 to 1-6.

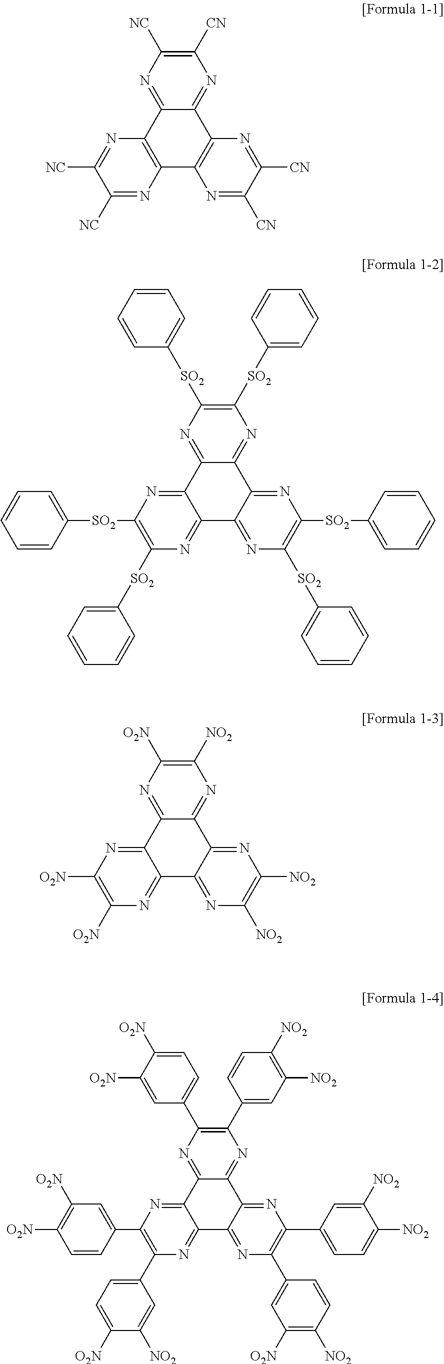

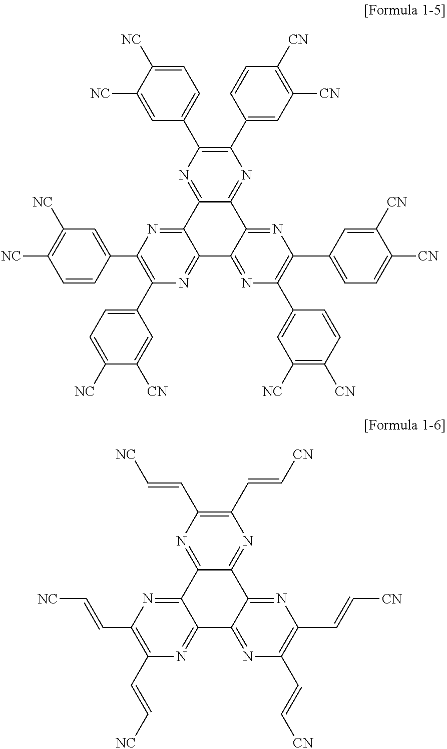

The organic light emitting device according to the present invention may be manufactured by using the same material and method as those known in the art, except that the organic material layer that is contacted with the second electrode includes the metal oxide among the organic material layers in the structure in which the substrate, the first electrode, two or more organic material layers and the second electrode are layered.

However, as described above, since the present invention is not largely limited to the method for forming the second electrode layered on the organic material layer, the selection of the material and the forming process of the second electrode is variously carried out as compared to a known technology.

For example, in the present invention, the second electrode may use a thin film forming technology of providing damage to the organic material layer by accompanying electric charges or particles having high kinetic energy like sputtering, a physical vapor deposition (PVD) method using a laser, an ion beam assisted deposition method or a similar method. Accordingly, an electrode material that is capable of being formed by only using the above methods may be used. For example, the second electrode may be formed by using a transparent conductive oxide material in a visible ray area, or Al, Ag, Au, Ni, Pd, Ti, Mo, Mg, Ca, Zn, Te, Pt, Ir or an alloy material that includes one or more of them like IZO (indium doped zinc-oxide) or ITO (indium doped tin-oxide).

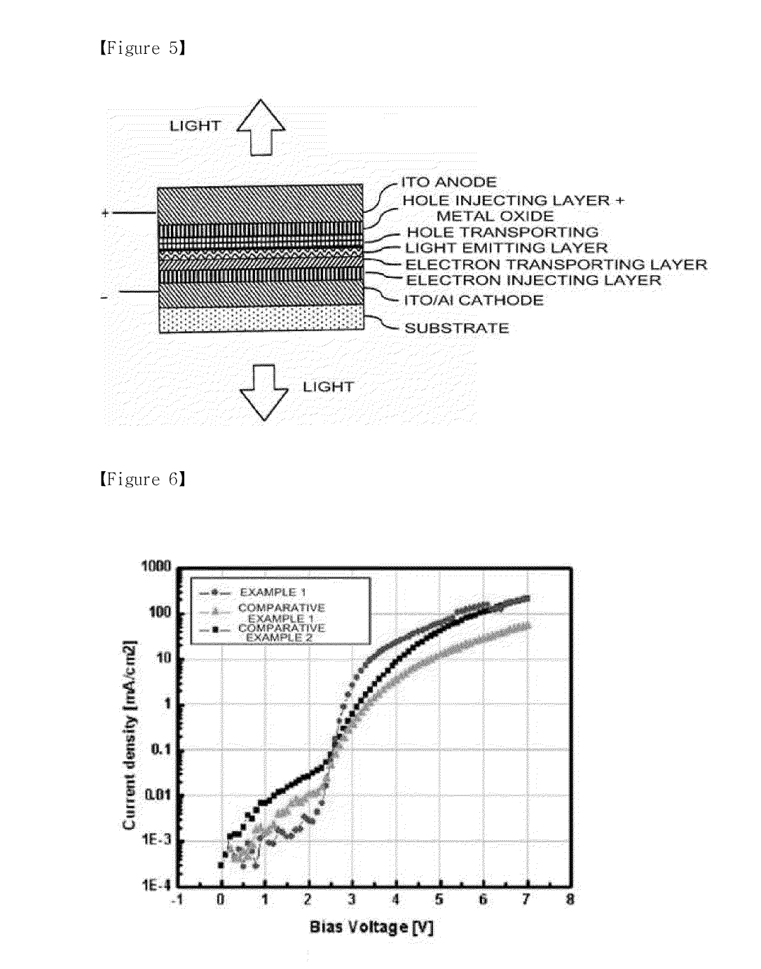

Examples of the organic light emitting device according to the present invention are shown in FIGS. 4 and 5. FIG. 4 illustrates the top emission device, and FIG. 5 illustrates the both-side light emitting device. However, the structure of the organic light emitting device according to the present invention is not limited thereto.

Among the organic light emitting devices according to the present invention, the organic material layer may have a single layer structure, but have a multilayered structure in which two or more organic material layers are layered. For example, the organic light emitting device according to the present invention may have a structure that includes a hole injecting layer, a hole transporting layer, a light emitting layer, an electron transporting layer, the electron injecting layer and a buffer layer that is disposed between the anode and the hole injecting layer as the organic material layer. However, the structure of the organic light emitting device is not limited thereto, but it may include the smaller number of organic material layers.

### MODE FOR INVENTION

A better understanding of the present invention may be obtained in light of the following Examples which are set forth to illustrate, but are not to be construed to limit the present invention.

### Example 1

The cathode (Al) that had the thickness of 150 nm and the electron injecting layer (LiF) that had the thickness of 1.5 nm were sequentially formed on the glass substrate by using a thermal evaporation process. Subsequently, on the electron injecting layer, the electron transporting layer was formed in a thickness of 20 nm.

Subsequently, on the electron transporting layer, C545T (10-(2-benzotriazolyl)-1,1,7,7-tetramethyl-2,3,6,7-tetrahydro-1H,5H,11H-1)benzo pyrono[6,7,8-ij]quinolizin-11-on) was co-deposited in an amount of 1 wt % on the Alq3 light emitting host to form a light emitting layer having a thickness of 30 nm. On the light emitting layer, the NPB(4,4′-bis[N-(1-naphthyl)-N-phenylamino]biphenyl) thin film was deposited in a thickness of 40 nm as the hole transporting layer. On the hole transporting layer, by doping metal oxide (MoO₃) onto the compound of the following Formula 1-1 to form a layer having a thickness of 70 nm as the hole injecting layer.

On the organic material layer that includes the metal oxide, an IZO anode having a thickness of 150 nm was formed by using the sputtering method at a rate of 1.3 Å/sec to manufacture a top emission organic light emitting device.

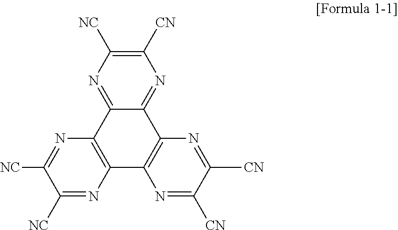

### Comparative Example 1

The cathode (Al) that had the thickness of 150 nm and the electron injecting layer (LiF) that had the thickness of 1.5 nm were sequentially formed on the glass substrate by using a thermal evaporation process. Subsequently, on the electron injecting layer, the electron transporting layer was formed in a thickness of 20 nm.

Subsequently, on the electron transporting layer, C545T (10-(2-benzotriazolyl)-1,1,7,7-tetramethyl-2,3,6,7-tetrahydro-1H,5H,11H-1)benzo pyrono[6,7,8-ij]quinolizin-11-on) was co-deposited in an amount of 1 wt % on the Alq3 light emitting host to form a light emitting layer having a thickness of 30 nm. On the light emitting layer, the NPB(4,4′-bis[N-(1-naphthyl)-N-phenylamino]biphenyl) thin film was deposited in a thickness of 40 nm as the hole transporting layer. On the hole transporting layer, a layer having a thickness of 70 nm was formed by using the compound of Formula 1-1 as the hole injecting layer. A metal oxide layer having a thickness of 5 nm was formed by using metal oxide (MoO₃).

On the organic material layer that includes the metal oxide, an IZO anode having a thickness of 150 nm was formed by using the sputtering method at a rate of 1.3 Å/sec to manufacture a top emission organic light emitting device.

### Comparative Example 2

The cathode (Al) that had the thickness of 150 nm and the electron injecting layer (LiF) that had the thickness of 1.5 nm were sequentially formed on the glass substrate by using a thermal evaporation process. Subsequently, on the electron injecting layer, the electron transporting layer was formed in a thickness of 20 nm.

Subsequently, on the electron transporting layer, C545T (10-(2-benzotriazolyl)-1,1,7,7-tetramethyl-2,3,6,7-tetrahydro-1H,5H,11H-1)benzo pyrono[6,7,8-ij]quinolizin-11-on) was co-deposited in an amount of 1 wt % on the Alq3 light emitting host to form a light emitting layer having a thickness of 30 nm. On the light emitting layer, the NPB(4,4′-bis[N-(1-naphthyl)-N-phenylamino]biphenyl) thin film was deposited in a thickness of 40 nm as the hole transporting layer. On the hole transporting layer, a layer having a thickness of 70 nm was formed by using the compound of Formula 1-1 as the hole injecting layer.

On the hole injecting layer, an IZO anode having a thickness of 150 nm was formed by using the sputtering method at a rate of 1.3 Å/sec to manufacture a top emission organic light emitting device.

### Experimental Example

### Leakage Current Property

The current-voltage (I-V) property was measured by using the HP4155C device. The leakage current is defined by a current density level at a voltage (<˜2 V) before the organic light emitting device is operated, and stability of the device is ensured when the amount of leakage current is small. The above results are shown in FIG. 6.

Luminance Property

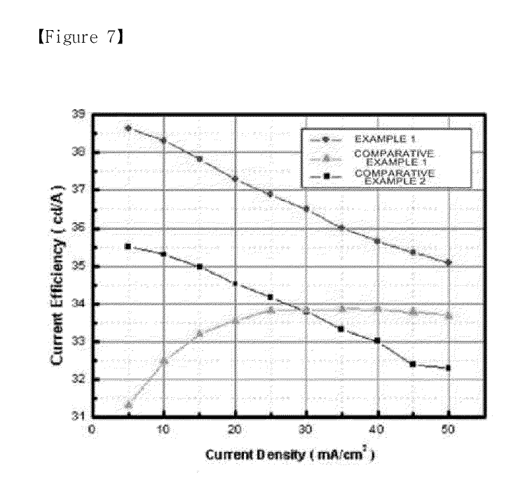

The current density-voltage-luminance (J-V-L) property was measured by using a Photo Research PR650 spectrophotometer and Keithley 2400 that was capable of being controlled by a computer. The results are shown in FIG. 7.

It was confirmed that the organic light emitting device that was manufactured by doping the metal oxide into the organic material layer that is contacted with the second electrode according to Example 1 had the best leakage current and luminance property, and the organic light emitting device that was manufactured by depositing the metal oxide layer according to Comparative Example 1 has a problem in that the luminance was reduced at low voltage.

In Example 1, MoO₃ that was used as the doping material of the compound of Formula 1-1 had the work function of about 5.3 eV. In the case of when the metal oxide having the work function that was higher than that of IZO (4.7 ev) was used as the doping material, an excellent effect may be obtained.

Therefore, in the case of when V₂O₅ (5.3 eV) having the similar work function to MoO3 and WO3 (6.4 eV) having the work function that was higher than that of MoO₃ were used as the doping material of the compound of Formula 1-1, it could be estimated that the same effect or the better effect in respects to that of Example 1 could be ensured.

In addition, in the case of when ITO that was used as the anode material in Example 1, had almost the same work function, conductivity and transparency as IZO, and was manufactured by using the same deposition method was used as the anode material, it could be estimated that the same effect in respects to that of Example 1 could be ensured.

Therefore, the present invention may make it possible to manufacture the organic light emitting device that includes a substrate, a first electrode, two or more organic material layers and a second electrode are sequentially layered, in which since metal oxide is included in the organic material layer that is contacted with the second electrode among the organic material layers, luminance is not reduced at low voltage, and in the case of when properties of the hole transporting layer (HTL) material and the metal oxide are mixed, the leakage current that is a problem of a hole transporting layer (HTL) is largely reduced without an increase in operation voltage.

1. An organic light emitting device that comprises a substrate, a first electrode, two or more organic material layers, and a second electrode sequentially layered, wherein the organic material layers include a light emitting layer, and among the organic material layers, the organic material layer that is contacted with the second electrode includes metal oxide.

2. The organic light emitting device as set forth in claim 1, wherein the metal oxide comprises one or more that are selected from the group consisting of MoO₃, WO₃ and V₂O₅.

3. The organic light emitting device as set forth in claim 1, wherein the metal oxide is included in a concentration of 1 wt % or more and less than 100 wt % in the organic material layer that is contacted with the second electrode.

4. The organic light emitting device as set forth in claim 1, wherein the organic light emitting device is a top light emitting device or a both-side light emitting device.

5. The organic light emitting device as set forth in claim 1, wherein the second electrode is formed by a thin film forming technology that is capable of providing a damage to the organic material layer without the presence of the organic material layer including the metal oxide by accompanying particles having electric charges or high kinetic energy.

6. The organic light emitting device as set forth in claim 5, wherein the thin film forming technology is selected from the group consisting of sputtering, a physical deposition method using a laser, and a deposition method using an ion beam.

7. The organic light emitting device as set forth in claim 1, wherein the first electrode is a cathode, the second electrode is an anode, and the device is manufactured by first forming the cathode on the substrate, and sequentially forming two or more organic material layers and the anode on the cathode.

8. The organic light emitting device as set forth in claim 1, wherein the second electrode is metal having a work function in the range of 2 to 6 eV or a conductive oxide film.

9. The organic light emitting device as set forth in claim 1, wherein the second electrode is an ITO (Indium tin Oxide) or an IZO (Indium Zinc Oxide).

10. The organic light emitting device as set forth in claim 1, wherein the organic material layer that is contacted with the second electrode is a hole injecting layer.

11. The organic light emitting device as set forth in claim 10, wherein the organic material layer that is contacted with the second electrode comprises one or more compounds that are represented by the following Formula 1: 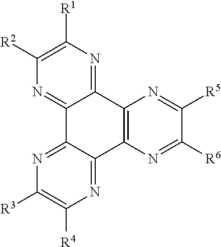
wherein R¹ to R⁶ are each selected from the group consisting of hydrogen, a halogen atom, nitrile (—CN), nitro (—NO₂), sulfonyl (—SO₂R), sulfoxide (—SOR), sulfonamide (—SO₂NR), sulfonate (—SO₃R), trifluoromethyl (—CF₃), ester (—COOR), amide (—CONHR or —CONRR′), substituted or unsubstituted straight- or branched-chained C₁-C₁₂ alkoxy, substituted or unsubstituted straight- or branched-chained C₁-C₁₂ alkyl, substituted or unsubstituted aromatic or non-aromatic heterocycle, substituted or unsubstituted aryl, substituted or unsubstituted mono- or di-arylamine, and substituted or unsubstituted aralkylamine, and R and R′ are each selected from the group consisting of substituted or unsubstituted C₁-C₆₀ alkyl, substituted or unsubstituted aryl and substituted or unsubstituted 5-7 membered heterocycle.

12. The organic light emitting device as set forth in claim 11, wherein the compound of Formula 1 is a compound that is represented by the following Formula 1-1 to 1-6:

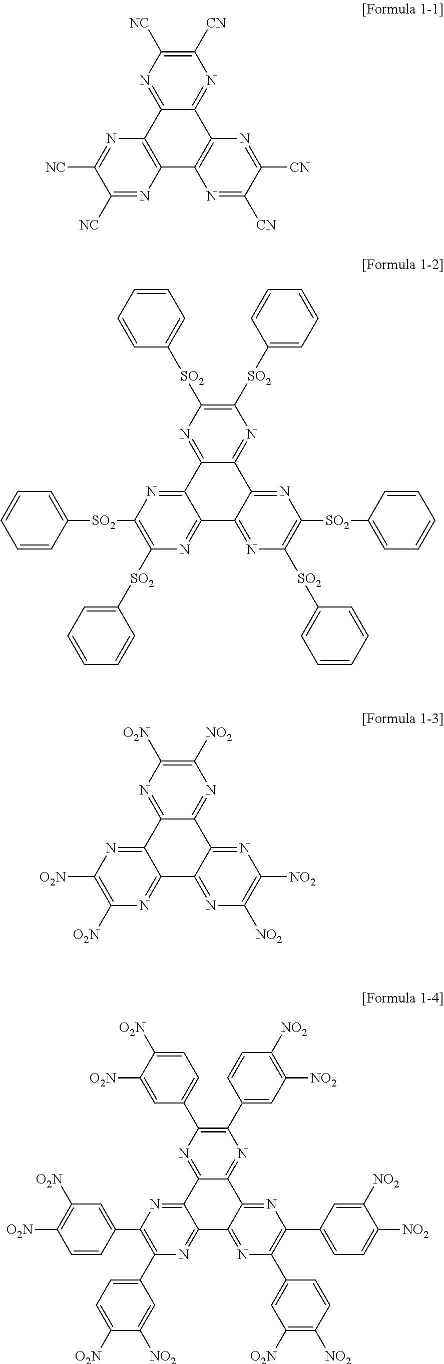

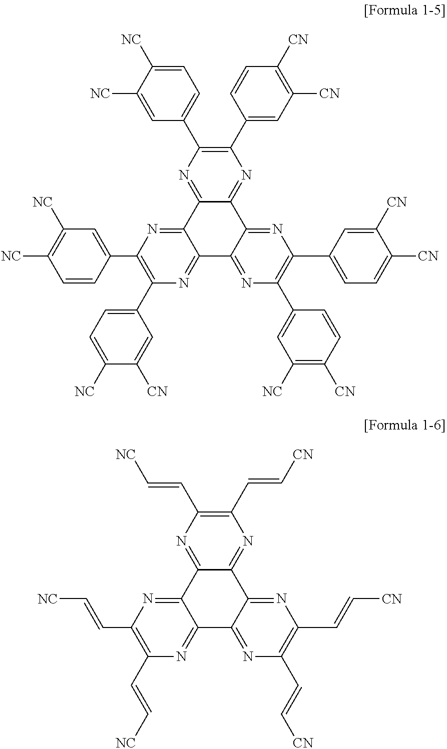

13. The organic light emitting device as set forth in claim 1, wherein the thickness of the organic material layer that is contacted with the second electrode is 20 nm or more.

14. A method for manufacturing an organic light emitting device, which comprises the steps of sequentially layering a first electrode, two or more organic material layers and a second electrode on a substrate, wherein one layer of the organic material layers is formed as a light emitting layer and the organic material layer that is contacted with the second electrode among the organic material layers is formed by doping metal oxide into an organic material.

15. The method for manufacturing an organic light emitting device as set forth in claim 14, wherein the second electrode is formed by a thin film forming technology that is capable of providing a damage to the organic material layer without the presence of the organic material layer including the metal oxide by accompanying particles having electric charges or high kinetic energy.
